(19) United States
(12) Patent Application Publication
(10) Pub. No.: US 2013/0270542 A1
(43) Pub. Date: Oct. 17, 2013

(54) METHOD FOR PRODUCING AN OPTOELECTRONIC COMPONENT AND OPTOELECTRONIC COMPONENT

(71) Applicant: Daniel Steffen Setz, Muenchen (DE)

(72) Inventor: Daniel Steffen Setz, Muenchen (DE)

(73) Assignee: OSRAM OPTO SEMICONDUCTORS GMBH, Regensburg (DE)

(21) Appl. No.: 13/995,515

(22) PCT Filed: Dec. 14, 2011
(86) PCT No.: PCT/EP11/72710

§ 371 Date: Jun. 19, 2013

(30) Foreign Application Priority Data
Dec. 20, 2010 (DE) 102010063511.1

(51) Int. Cl. H01L 51/52; H01L 51/56

(52) U.S. Cl. CPC H01L 51/5262; H01L 51/56
USPC 257/40; 438/29

(57) ABSTRACT

A method for producing an optoelectronic component includes forming an organic functional layer structure on or above a first electrode layer, and forming a second electrode layer on or above the organic functional layer structure, wherein a local modification structure is formed in the first electrode layer or in the second electrode layer.

### RELATED APPLICATIONS

The present application is a national stage entry according to 35 U.S.C. §371 of PCT application No.: PCT/EP2011/072710 filed on Dec. 14, 2011, which claims priority from German application No.: 102010063511.1 filed on Dec. 20, 2010.

### TECHNICAL FIELD

Various embodiments relate to a method for producing an optoelectronic component and to an optoelectronic component.

### BACKGROUND

In an organic light emitting diode, the light generated by said organic light emitting diode is partly coupled out directly from the organic light emitting diode. The rest of the light is distributed into various loss channels, as is illustrated in an illustration of an organic light emitting diode 100 in FIG. 1. FIG. 1 shows an organic light emitting diode 100 comprising a glass substrate 102 and a transparent first electrode layer 104 composed of indium tin oxide (ITO) and arranged on said glass substrate. Arranged on the first electrode layer 104 is a first organic layer 106, on which an emitter layer 108 is arranged. A second organic layer 110 is arranged on the emitter layer 108. Furthermore, a second electrode layer 112, composed of a metal is arranged on the second organic layer 110. An electric current supply 114 is coupled to the first electrode layer 104 and to the second electrode layer 112, such that an electric current for generating light is passed through the layer structure arranged between the electrode layers 104, 112. A first arrow 116 symbolizes a transfer of electrical energy into surface plasmons in the second electrode layer 112. A further loss channel can be seen in absorption losses in the light emission path (symbolized by means of a second arrow 118). Light coupled out from the organic light emitting diode 100 is, for example, a portion of the light which arises on account of a reflection of a portion of the generated light at the interface between the glass substrate 102 and air (symbolized by means of a third arrow 122) and on account of a reflection of a portion of the generated light at the interface between the first electrode layer 104 and the glass substrate 102 (symbolized by means of a fourth arrow 124). That portion of the generated light which is coupled out from the glass substrate 102 is symbolized by means of a fifth arrow 120 in FIG. 1. Therefore, for example the following loss channels are clearly present: light loss in the glass substrate 102, light loss in the organic layers 106, 110 and surface plasmons generated at the metallic cathode (second electrode layer 112). These light portions cannot readily be coupled out from the organic light emitting diode 100.

For coupling out substrate modes, so-called coupling-out films are conventionally applied on the underside of the substrate of an organic light emitting diode, and can couple the light out from the substrate by means of optical scattering or by means of microlenses. It is furthermore known to structure the free substrate surface directly. However, such a method considerably influences the appearance of the organic light emitting diode. A milky surface of the substrate arises as a result.

For coupling out the light in the organic layers of the organic light emitting diode, various approaches currently exist, but as yet none of these approaches has matured to product readiness.

These approaches are, inter alia:
Introducing periodic structures into the active layers of the organic light emitting diode (photonic crystals). However, these have a very great dependence on wavelength since the photonic crystals can only couple out specific wavelengths.
Using a high refractive index substrate for directly coupling the light of the organic layers into the substrate. This approach is very cost-intensive on account of the high costs for a high refractive index substrate. Furthermore, a high refractive index substrate relies on further coupling-out aids in the form of microlenses, scattering films (each having a high refractive index) or surface structurings.

### SUMMARY

Various exemplary embodiments make it possible to produce structures within an optoelectronic component, for example within an organic light emitting diode, which structures can be used to couple out for example both the light in a substrate and the light in one or more organic layers of the optoelectronic component. By way of example, the structures can be produced by means of local heating (for example melting) of the respective material in which the structures are intended to be formed, for example by means of laser internal engraving.

Various exemplary embodiments provide a method for producing an optoelectronic component. The method can comprise forming an organic functional layer structure on or above a first electrode layer; forming a second electrode layer on or above the organic functional layer structure; and forming in at least one of the layers of the optoelectronic component at at least one predefined position a local modification structure of the material of the respective layer.

In one configuration, at at least one predefined position a local modification structure, for example a plurality of local modification structures, can be formed by means of locally heating the material of the respective layer.

In yet another configuration, the local heating of the material of the respective layer can be effected using a laser.

In yet another configuration, the local heating of the material of the respective layer can be effected using the laser in such a way that a laser internal engraving of the respective layer is carried out.

In yet another configuration, a local modification structure (or a plurality of local modification structures) can be formed in the first electrode layer or in the second electrode layer.

In yet another configuration, the method can furthermore comprise forming the first electrode layer on or above a substrate; and/or forming a cover layer on or above the second electrode layer.

In yet another configuration, a local modification structure (or a plurality of local modification structures) can be formed in the substrate.

In yet another configuration, a local modification structure (or a plurality of local modification structures) can be formed in the cover layer.

In yet another configuration, the method can furthermore comprise forming an optically transparent intermediate layer (which becomes an optically translucent intermediate layer, if appropriate, in the course of formation of one or a plurality of local modification structures) on or above the substrate, wherein the first electrode layer is formed on or above the optically transparent intermediate layer (or if appropriate optically translucent intermediate layer); and/or forming an encapsulation layer on or above the second electrode layer.

In various exemplary embodiments, the term “translucent layer” can be understood to mean that a layer is transmissive to light, for example to the light generated by the optoelectronic component, for example in one or more wavelength ranges, for example to light in a wavelength range of visible light (for example at least in a partial range of the wavelength range of from 380 nm to 780 nm). By way of example, in various exemplary embodiments, the term “translucent layer” should be understood to mean that substantially the entire quantity of light coupled into a structure (for example a layer) is also coupled out from the structure (for example layer).

In various exemplary embodiments, the term “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion.

In yet another configuration, a local modification structure (or a plurality of local modification structures) can be formed in the optically transparent intermediate layer, whereby the optically transparent intermediate layer becomes an optically translucent intermediate layer.

In yet another configuration, a local modification structure (or a plurality of local modification structures) can be formed in the encapsulation layer.

In yet another configuration, that layer in which a local modification structure (or a plurality of local modification structures) is formed can be formed with a layer thickness of at least 1 μm.

In various configurations, a local modification structure (or a plurality of local modification structures) can also be formed at an interface between two layers of the optoelectronic component. In such a configuration, the sum of the layer thicknesses of the two layers at whose interface the local modification structure (or the plurality of local modification structures) is (are) intended to be formed can be at least 1 μm.

In yet another configuration, the local modification structure (or the plurality of local modification structures) can be formed with a size in the sub-micrometer range.

In a configuration in which a plurality of local modification structures are formed with a size in the sub-micrometer range, the local modification structures can be formed, in a non-periodic, to put it another way random, pattern, that is to say without a regular order.

In yet another configuration, the local modification structure (or the plurality of local modification structures) can be formed with a size of at least one micrometer.

In a configuration in which a plurality of local modification structures are formed with a size of at least one micrometer, the local modification structures can be formed in a regular, for example periodic, pattern.

In yet another configuration, a local deterministic structure (for example an optical lens structure) can be formed as local modification structure(s)).

Various exemplary embodiments provide an optoelectronic component. The optoelectronic component can comprise a first electrode layer; an organic functional layer structure on or above the first electrode layer; and a second electrode layer on or above the organic functional layer structure; wherein at least one of the layers of the optoelectronic component has a local modification structure of the material of the respective layer at at least one predefined position.

In one configuration, a local modification structure can be formed in the first electrode layer or in the second electrode layer.

In yet another configuration, the optoelectronic component can furthermore comprise a substrate, wherein the first electrode layer is arranged on or above the substrate; and/or a cover layer on or above the second electrode layer.

In yet another configuration, a local modification structure can be formed in the substrate and/or in the cover layer.

In yet another configuration, the optoelectronic component can furthermore comprise an optically transparent intermediate layer (or optically translucent intermediate layer) on or above the substrate, wherein the first electrode layer is arranged on or above the optically transparent intermediate layer (or optically translucent intermediate layer); and/or an encapsulation layer on or above the second electrode layer.

In yet another configuration, a local modification structure (or a plurality of local modification structures) can be formed in the optically transparent intermediate layer (or optically translucent intermediate layer).

In yet another configuration, a local modification structure (or a plurality of local modification structures) can be formed in the encapsulation layer.

In yet another configuration, that layer which has a local modification structure (or a plurality of local modification structures) can have a layer thickness of at least 1 μm.

In various configurations, a local modification structure (or a plurality of modification structures) can also be formed at an interface between two layers of the optoelectronic component. In such a configuration, the sum of the layer thicknesses of the two layers at whose interface the local modification structure (or a plurality of local modification structures) is (are) intended to be formed can be at least 1 μm.

In yet another configuration, the local modification structure (or the plurality of local modification structures) can have a size in the sub-micrometer range.

In a configuration in which a plurality of local modification structures are formed with a size in the sub-micrometer range, the local modification structures can be formed in a non-periodic, to put it another way random, pattern, that is to say without a regular order.

In yet another configuration, the local modification structure (or the plurality of local modification structures) can be formed with a size of at least one micrometer.

In a configuration in which a plurality of local modification structures are formed with a size of at least one micrometer, the local modification structures can be formed in a regular, for example periodic, pattern.

In yet another configuration, a local deterministic structure (for example an optical lens structure) can be formed as local modification structure(s).

It should be pointed out that the one or the plurality of local modification structure(s) can be formed in such a way that it or they is or are scarcely perceptible to a human eye, but nevertheless scatters or scatter a portion of the light, in order thus to improve the coupling-out of the light.

### BRIEF DESCRIPTION OF THE DRAWINGS

Exemplary embodiments of the invention are illustrated in the figures and are explained in greater detail below.

In the figures:

FIG. 1 shows an illustration of a conventional organic light emitting diode;

FIG. 2 shows an organic light emitting diode in accordance with various exemplary embodiments;

FIG. 3 shows an organic light emitting diode in accordance with various exemplary embodiments;

FIG. 4 shows an organic light emitting diode in accordance with various exemplary embodiments;

FIG. 5 shows an organic light emitting diode in accordance with various exemplary embodiments;

FIG. 6 shows an organic light emitting diode in accordance with various exemplary embodiments;

FIG. 7 shows an organic light emitting diode in accordance with various exemplary embodiments;

FIG. 8 shows an organic light emitting diode in accordance with various exemplary embodiments; and

FIG. 9 shows a flowchart illustrating a method for producing an optoelectronic component in accordance with various exemplary embodiments.

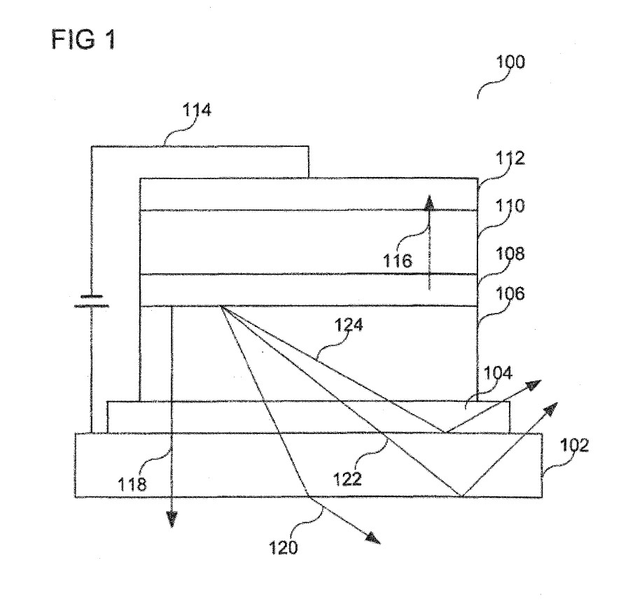

### DETAILED DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various exemplary embodiments described herein can be combined with one another, unless specifically indicated otherwise. Therefore, the following detailed description should not be interpreted in a restrictive sense, and the scope of protection of the present invention is defined by the appended claims. Identical or similar elements are provided with identical reference signs in the figures, insofar as this is expedient.

In the context of this description, the terms “connected” and “coupled” are used to describe both a direct and an indirect connection and a direct or indirect coupling. In the figures, identical or similar elements are provided with identical reference signs, insofar as this is expedient.

In various exemplary embodiments, the optoelectronic component can be embodied as an organic light emitting diode (OLED), as an organic photodiode (OPD), as an organic solar cell (OSC), or as an organic transistor, for example as an organic thin film transistor (OTFT). In various exemplary embodiments, the optoelectronic component can be part of an integrated circuit.

Furthermore, a plurality of optoelectronic components can be provided, for example in a manner accommodated in a common housing.

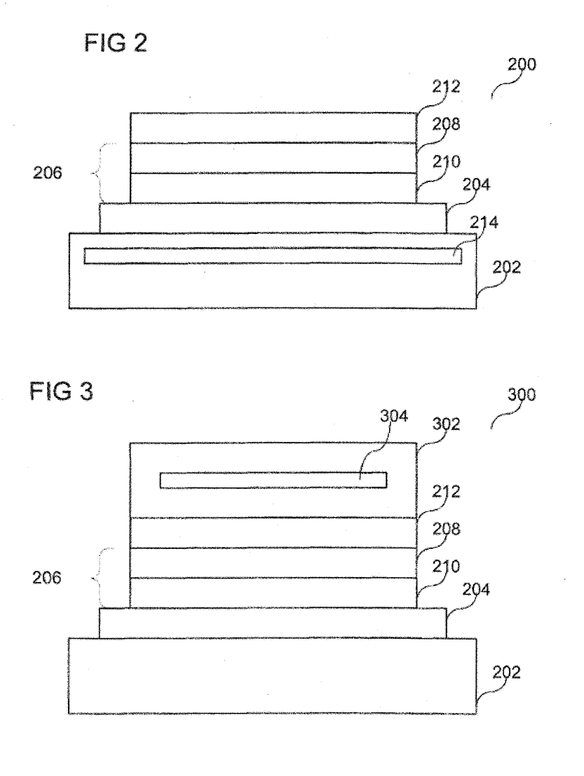

FIG. 2 shows an organic light emitting diode 200 as an implementation of an optoelectronic component in accordance with various exemplary embodiments.

The optoelectronic component in the form of an organic light emitting diode 200 can have a substrate 202. The substrate 202 can serve for example as a carrier element for electronic elements or layers, for example optoelectronic elements. By way of example, the substrate 202 can comprise or be formed from glass, quartz, and/or a semiconductor material or any other suitable material. Furthermore, the substrate 202 can comprise or be formed from a plastic film or a laminate comprising one or comprising a plurality of plastic films. The plastic can comprise or be formed from one or more polyolefins (for example high or low density polyethylene (PE) or polypropylene (PP)). Furthermore, the plastic can comprise or be formed from polyvinyl chloride (PVC), polystyrene (PS), polyester and/or polycarbonate (PC), polyethylene terephthalate (PET), polyether sulfone (PES) and/or polyethylene naphthalate (PEN). Furthermore, the substrate 202 can comprise for example a metal film, for example an aluminum film, a high-grade steel film, a copper film or a combination or a layer stack thereon. The substrate 202 can comprise one or more of the materials mentioned above. The substrate 202 can be embodied as transparent, partly transparent or else opaque.

A first electrode 204 (for example in the form of a first electrode layer 204) can be applied on or above the substrate 202. The first electrode 204 (also designated hereinafter as bottom electrode 204) can be formed from or be an electrically conductive material, such as, for example, a metal or a transparent conductive oxide (TCO) or a layer stack comprising a plurality of layers of the same or different metal or metals and/or the same or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs. Furthermore, the TCOs do not necessarily correspond to a stoichiometric composition and can furthermore be p-doped or n-doped. The first electrode 204 can be embodied as an anode, that is to say as a hole-injecting material.

In various exemplary embodiments, the first electrode 204 can be formed by a layer stack of a combination of a layer of a metal on a layer of a TCO, or vice versa. One example is a silver layer applied on an indium tin oxide layer (ITO) (Ag on ITO). In various exemplary embodiments, the first electrode 204 can comprise a metal (for example Ag, Pt, Au, Mg) or comprise a metal alloy of the materials described (for example an AgMg alloy). In various exemplary embodiments, the first electrode 204 can comprise AlZnO or similar materials.

In various exemplary embodiments, the first electrode 204 can comprise a metal, which can serve for example as cathode material, that is to say as electron-injecting material. In various exemplary embodiments, inter alia for example Al, Ba, In, Ag, Au, Mg, Ca or Li and compounds, combinations or alloys of these materials can be provided as cathode material.

For the case where the optoelectronic component 200 is designed as a bottom emitter, the first electrode 204 (in particular first metal electrode 204) can have for example a layer thickness of less than or equal to approximately 25 nm, for example a layer thickness of less than or equal to approximately 20 nm, for example a layer thickness of less than or equal to approximately 18 nm. Furthermore, the first electrode 204 can have for example a layer thickness of greater than or equal to approximately 10 nm, for example a layer thickness of greater than or equal to approximately 15 nm. In various exemplary embodiments, the first electrode 204 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

For the case where the optoelectronic component 200 is designed as a top emitter, then the first electrode 204 can have for example a layer thickness of greater than or equal to approximately 40 nm, for example a layer thickness of greater than or equal to approximately 50 nm.

Furthermore, the optoelectronic component 200 can have an organic functional layer structure 206, which has been or is applied on or above the first electrode 204.

The organic functional layer structure 206 can contain one or a plurality of emitter layers 208, for example comprising fluorescent and/or phosphorescent emitters, and one or a plurality of hole-conducting layers 210.

Examples of emitter materials which can be used in the optoelectronic component in accordance with various exemplary embodiments for the emitter layer(s) 208 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl-(2-carboxypyridyl)-iridium III), green phosphorescent Ir(ppy)₃ (tris (2-phenylpyridine) iridium III), red phosphorescent Ru (dtb-bpy)₃*2(PF₆) (tris[4,4′-di-tert-butyl-(2,2′)-bipyridine]ruthenium (III) complex) and blue fluorescent DPAVBi (4,4-bis[4-(di-p-tolylamino) styryl]biphenyl), green fluorescent TTPA (9,10-bis[N,N-di-(p-tolyl)-amino]anthracene) and red fluorescent DCM2 (4-dicyanomethylene)-2-methyl-6-julolidyl-9-enyl-4H-pyran) as non-polymeric emitters. Such non-polymeric emitters can be deposited by means of thermal evaporation, for example. Furthermore, it is possible to use polymer emitters, which can be deposited, in particular, by means of wet-chemical methods such as spin coating, for example.

The emitter materials can be embedded in a matrix material in a suitable manner.

The emitter materials of the emitter layer(s) 208 of the optoelectronic component 200 can be selected for example such that the optoelectronic component 200 emits white light. The emitter layer(s) 208 can comprise a plurality of emitter materials that emit in different colors (for example blue and yellow or blue, green and red); alternatively, the emitter layer(s) 208 can also be constructed from a plurality of partial layers, such as a blue fluorescent emitter layer 208 or blue phosphorescent emitter layer 208, a green phosphorescent emitter layer 208 and a red phosphorescent emitter layer 208. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic functional layer structure 206 can generally comprise one or a plurality of functional layers. The one or the plurality of functional layers can comprise organic polymers, organic oligomers, organic monomers, organic small, non-polymer molecules (“small molecules”) or a combination of these materials. By way of example, the organic functional layer structure 206 can comprise one or a plurality of functional layers embodied as a hole transport layer 210, so as to enable for example in the case of an OLED an effective hole injection into an electroluminescent layer or an electroluminescent region. By way of example, tertiary amines, carbazo derivatives, conductive polyaniline or polyethylene dioxythiophene can be used as material for the hole transport layer 210. In various exemplary embodiments, the one or the plurality of functional layers can be embodied as an electroluminescent layer.

In various exemplary embodiments, the hole transport layer 210 can be applied, for example deposited, on or above the first electrode 204, and the emitter layer 208 can be applied, for example deposited, on or above the hole transport layer 210.

The optoelectronic component 200 can generally comprise further organic functional layers that serve to further improve the functionality and thus the efficiency of the optoelectronic component 200.

The optoelectronic component 200 can be embodied as a “bottom emitter” and/or a “top emitter”.

In various exemplary embodiments, the organic functional layer structure 206 can have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various exemplary embodiments, the organic functional layer structure 206 can have for example a stack of a plurality of OLEDs arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various exemplary embodiments, the organic functional layer structure 206 can have for example a stack of three or four OLEDs arranged directly one above another, in which case for example the organic functional layer structure 206 can have a layer thickness of a maximum of approximately 3 μm.

A second electrode 212 (for example in the form of a second electrode layer 212) can be applied on or above the organic functional layer structure 206.

In various exemplary embodiments, the second electrode 212 can comprise or be formed from the same materials as the first electrode 204, metals being particularly suitable in various exemplary embodiments.

In various exemplary embodiments, the second electrode 212 can have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm. In various exemplary embodiments, the second electrode 212 can have an arbitrarily greater layer thickness.

As is illustrated in FIG. 2, for the purpose of coupling out the substrate modes within the substrate (for example glass substrate) 202 at at least one predefined position (or at a plurality of predefined positions) (in each case) a local modification structure of the material of the substrate 202 is provided. In various exemplary embodiments, the local modification structure(s) are formed in the form of an engraving, for example in the form of a substrate internal engraving. In various exemplary embodiments, the local modification structure(s) is or are formed in the form of a non-periodic structure. This/these local modification structure(s) scatter(s) the light which is generated for example by the emitter layer 208 and which is guided into the substrate 202. One advantage of this configuration is that the surface of the substrate 202 (for example the glass surface) still retains its mirroring impression. As a result, the “off-state appearance” of the optoelectronic component 202 can additionally be improved. The one or the plurality of local modification structure(s) can be formed at predefined or predetermined positions within the substrate 202 (in the exemplary embodiments described below, if appropriate, in one or a plurality of other layers of the optoelectronic component), such that desired, artificially produced scattering structures (irregularities in the material of the respective layer that are not attributable to non-deterministic and undesired irregularities) are formed. The one or the plurality of local modification structure(s) can all have the same size or different sizes. The arrangement of a plurality of local modification structures in one or a plurality of layers can be random, to put it another way non-periodic. Alternatively, the local modification structures can be or have been arranged in a predefined (for example periodic) pattern. Furthermore, by means of the plurality of local modification structures, a local deterministic structure, for example a lens structure, can be formed in one or a plurality of layers.

If the local modification structures have a size in the sub-μm range, then various exemplary embodiments provide for the local modification structures to be arranged in a non-periodic pattern. If the local modification structures have a size of at least 1 μm, then various exemplary embodiments provide for the local modification structures to be arranged in a periodic pattern. However, it should be pointed out that also for the case where the local modification structures have a size of at least 1 μm, the local modification structures can be arranged non-periodically.

The organic light emitting diode 200 can be or have been formed as a bottom emitter or as a top and bottom emitter.

FIG. 3 shows an organic light emitting diode 300 as an implementation of an optoelectronic component in accordance with various exemplary embodiments.

In contrast to the organic light emitting diode 200 in accordance with FIG. 2, in this organic light emitting diode 300 in accordance with FIG. 3 no internal engraving is provided in the substrate 202. The organic light emitting diode 300 is embodied as a top emitter. Furthermore, the organic light emitting diode 300 has a cover layer 302, for example produced from glass or some other suitable material, such as, for example, one of the following materials: quartz, a semiconductor material, a plastic film or a laminate having one or having a plurality of plastic films. The plastic can comprise or be formed from one or a plurality of polyolefins (for example high or low density polyethylene (PE) or polypropylene (PP)). Furthermore, the plastic can comprise or be formed from polyvinyl chloride (PVC), polystyrene (PS), polyester and/or polycarbonate (PC), polyethylene terephthalate (PET), polyether sulfone (PES) and/or polyethylene naphthalate (PEN). The cover layer 302 can be embodied as translucent, for example transparent, partly translucent, for example partly transparent.

The cover layer 302 can have a layer thickness in a range of approximately 1 μm to approximately 50 μm, for example in a range of approximately 5 μm to approximately 40 μm, for example in a range of approximately 10 μm to approximately 25 μm.

In the organic light emitting diode 300 in accordance with FIG. 3, one or a plurality of local modification structure(s) is/are provided in the cover layer 302 and form scattering centers there, such as have been described by way of example above in connection with FIG. 2. Consequently, in the case of an organic light emitting diode 300 which emits on the top side, the coupling-out of light can be improved by virtue of, for example, the cover layer 302 (for example the cover glass) having one or a plurality of local modification structure(s) (for example in the form of an internal engraving).

Various exemplary embodiments can furthermore provide for introducing one or a plurality of local modification structure(s) if appropriate in the cover layer 302 (for example cover glass) and/or in the substrate 202, as a result of which, in the case of a transparent organic light emitting diode, too, an improvement in the coupling-out of light is made possible, without the transparency of the respective layer of the organic light emitting diode being influenced to an excessively great extent.

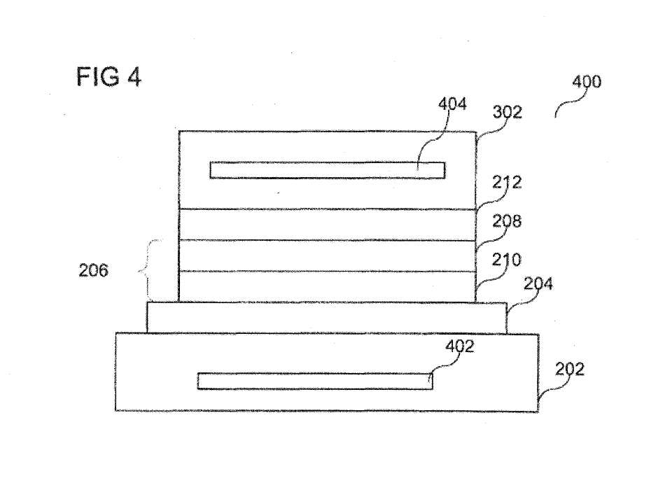

FIG. 4 shows an organic light emitting diode 400 as an implementation of an optoelectronic component in accordance with various exemplary embodiments.

The organic light emitting diode 400 in accordance with FIG. 4 is embodied as a top and bottom emitter and has, both in the substrate 202 and in the cover layer 302, in each case one or a plurality of local modification structure(s) 402, 404, such as have been described by way of example above in connection with FIG. 2.

For coupling out modes provided in the organic layers of an organic light emitting diode (e.g. organic light emitting diode 500), it may not suffice under certain circumstances to provide, for example internally engrave, the substrate 202 and/or the cover layer 302 with one or a plurality of local modification structure(s), since, on account of the jump in refractive index—usually present on account of the materials used—between the organic layers (for example the layers of the organic functional layer structure 206) (for example including the first electrode 204, for example the anode) having a refractive index in a range of approximately n=1.7 to approximately n=2 (for example having a refractive index in a range of approximately n=1.8 to approximately n=2, for example having a refractive index in a range of approximately n=1.7 to approximately n=1.8) and the substrate 202 having, for example, a refractive index of n=1.5 (for the case of a glass substrate), the light at least partly does not pass into the substrate 202 (for example the glass substrate 202). This aspect can be combated in various ways by means of the local modification structures.

Thus, by way of example, as illustrated in an organic light emitting diode 500 (see FIG. 5) as an implementation of an optoelectronic component in accordance with various exemplary embodiments, provision can be made of a transparent, high refractive index layer 502 (for example composed of silicon nitride and/or titanium oxide) or a stack 502 of a plurality of transparent, high refractive index layers between the substrate 202 and the first electrode 204, for example the anode 204. The one or the plurality of local modification structure(s) can be provided in the transparent, high refractive index layer 502 (or in the stack 502 of a plurality of transparent, high refractive index layers). By way of example, the transparent, high refractive index layer 502 (or the stack 502 of a plurality of transparent high refractive index layers) can be or have been internally engraved. The light coming from the layers of the organic functional layer structure 206 can be scattered in the transparent, high refractive index layer 502 (or in the stack 502 of a plurality of transparent, high refractive index layers), as a result of which it can be coupled out. In this case, by way of example, the engraving (generally the one or the plurality of local modification structure(s)) can also be provided at the interface between first electrode (anode) 204/high refractive index layer 502 or at the interface between substrate 202/high refractive index layer 502. In both cases, the light is likewise scattered.

In various exemplary embodiments, the transparent, high refractive index layer 502 can have a layer thickness in a range of approximately 1 μm to 50 μm, for example in a range of approximately 5 μm to approximately 40 μm, for example in a range of approximately 10 μm to approximately 25 μm.

Consequently, in various exemplary embodiments, the organic light emitting diode 500 in accordance with FIG. 5 is substantially identical to the organic light emitting diode 200 in accordance with FIG. 2, only with one or a plurality of additional layers between the substrate 202 and the first electrode 204, namely for example with the transparent, high refractive index layer 502 (or the stack 502 of a plurality of transparent, high refractive index layers). Furthermore, in this case, the substrate is not necessarily (but optionally possibly) provided with one or a plurality of local modification structure(s), but rather the transparent, high refractive index layer 502 (or the stack 502 of a plurality of transparent, high refractive index layers) (designated by reference sign 504 in FIG. 5).

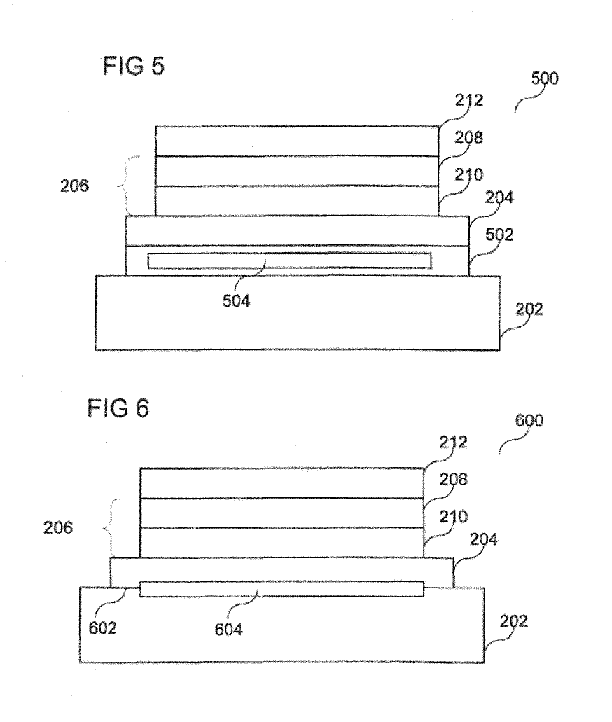

If a transparent, high refractive index layer 502 is not desired, then for example the interface 602 between the first electrode 204 (e.g. anode) and the substrate 202 can be or have been provided with one or a plurality of local modification structure(s) (designated by reference sign 604 in an organic light emitting diode 600 in FIG. 6), for example with an internal engraving, for example a laser internal engraving, in order to produce the light scattering at said interface 602. Consequently, clearly for example the transition between the substrate 202 and the transparent anode 204 is internally engraved in order to structure the interface 602 between high refractive index (for example anode 204) and low refractive index (for example substrate 202), in order that the light can be scattered there.

Consequently, in various exemplary embodiments, the organic light emitting diode 600 in accordance with FIG. 6 is substantially identical to the organic light emitting diode 200 in accordance with FIG. 2, only with one or a plurality of local modification structure(s), at the interface 602 between the first electrode 204 (e.g. anode) and the substrate 202. It should be pointed out that in a different implementation in the case of the organic light emitting diode 600 in accordance with FIG. 6, one or a plurality of local modification structure(s) can also be provided in the substrate 202.

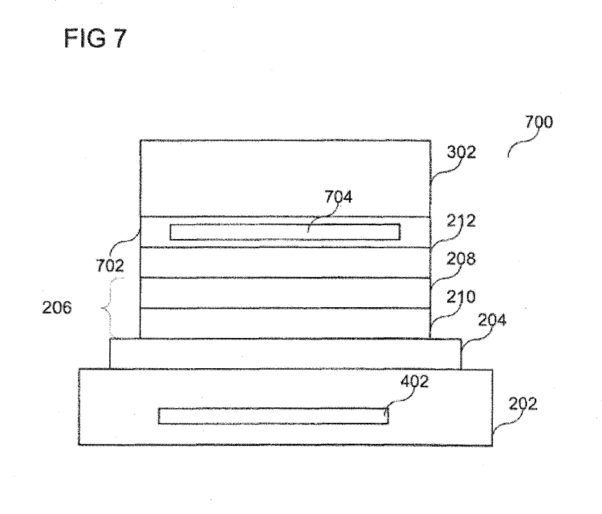

FIG. 7 shows yet another organic light emitting diode 700 in accordance with various exemplary embodiments.

In these exemplary embodiments, provision can be made for providing, in a case of a top emitting organic light emitting diode 700 or of a transparent organic light emitting diode, a thin-film encapsulation layer 702 between the then transparent second electrode (e.g. cathode) composed of a high refractive index material (for example a material having a refractive index in a range of approximately n=1.7 to approximately n=2 (for example having a refractive index in a range of approximately n=1.8 to approximately n=2, for example having a refractive index in a range of approximately n=1.7 to approximately n=1.8)) having a sufficient layer thickness (of at least 1 μm for example) and for providing said thin-film encapsulation layer 702 with one or a plurality of local modification structure(s) (designated by reference sign 704 in FIG. 7). In various exemplary embodiments, a layer (having the highest possible refractive index) can also be provided which is applied for example on the thin-film encapsulation layer 702.

In various exemplary embodiments, the expression “encapsulating” or “encapsulation” is understood to mean, for example, that a barrier against moisture and/or oxygen is provided, such that these substances cannot penetrate through the organic functional layer structure.

Consequently, in various exemplary embodiments, the organic light emitting diode 700 in accordance with FIG. 7 is substantially identical to the organic light emitting diode 400 in accordance with FIG. 4, the one or the plurality of local modification structure(s) being contained only or also in the thin-film encapsulation layer 702.

In various exemplary embodiments, the thin-film encapsulation layer 702 can comprise or consist of one or a plurality of the following materials: a material or a mixture of materials or a stack of layers of materials such as, for example, SiO₂, Si₃N₄; SiON (these materials are deposited by means of a CVD method, for example) ; Al₂O₃; ZrO₂; TiO₂; Ta₂O₅; SiO₂; ZnO; and/or HfO₂ (these materials are deposited by means of an ALD method, for example); or a combination of these materials.

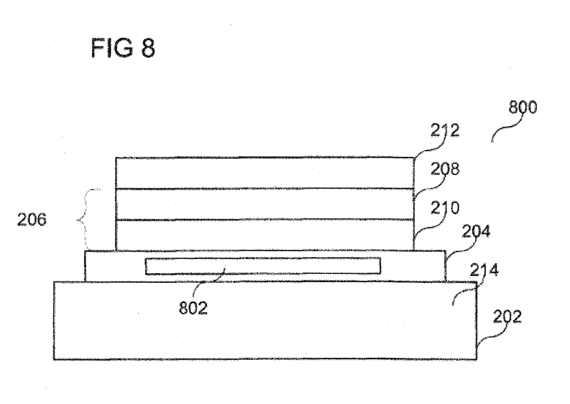

FIG. 8 shows yet another organic light emitting diode 800 in accordance with various exemplary embodiments.

In these exemplary embodiments, it can be provided that the first (in this case transparent) electrode 204 is or has been provided with one or a plurality of local modification structure(s) (designated by reference sign 802 in FIG. 8).

In various exemplary embodiments, a combination of a plurality of engraved layers can also be provided in the organic light emitting diode, generally in the optoelectronic component. Provision can also be made for engraving one or a plurality of layers only to a small extent, in order to obtain the transparency of the optoelectronic component whilst at the same time increasing the coupling-out of light.

The technique of internal engraving (using one or a plurality of lasers), for example, makes it possible to write or form arbitrary structures within the layers. In various exemplary embodiments, these can be for example particularly scattering layers; alternatively or additionally, it is also possible to write or form three-dimensional structures within one or a plurality of layers of the optoelectronic component, which can bring about lens effects, for example. As a result, it is also possible to create specific effects for the final application such as, for example, bright luminous script in the luminous image of the organic light emitting diode.

Since per se all optically translucent, for example transparent, materials can be provided for the laser internal engraving, for example, the substrate 202 or the cover layer 302 need not necessarily consist of glass. It is likewise possible for it to consist of or comprise for example plastic or other translucent, for example transparent, materials.

Consequently, in various exemplary embodiments, provision is made for coupling out the substrate modes and/or the modes of the other layers, for example the modes of the first electrode (for example ITO modes) and/or the modes of the organic system, that is to say of the organic layer structure; these modes are also designated as an ITO/organic system mode.

In various exemplary embodiments, the engraving can be formed up to a few nm close to the interfaces of a layer (however, the interface should not be destroyed, apart from the exemplary embodiments in which the interface is deliberately intended to be structured).

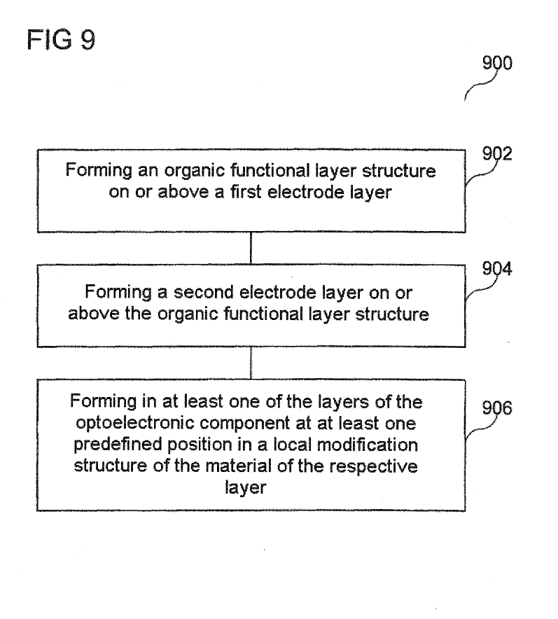

FIG. 9 shows a flowchart 900 illustrating a method for producing an optoelectronic component in accordance with various exemplary embodiments.

In various exemplary embodiments, in accordance with the method, in 902 an organic functional layer structure can be formed on or above a first electrode layer. Furthermore, in 904 a second electrode layer can be formed on or above the organic functional layer structure. Finally, in 906 in at least one of the layers of the optoelectronic component at at least one predefined position a local modification structure of the material of the respective layer can be formed.

The local modification structure can be formed by means of locally damaging the material structure of the respective layer, for example by means of locally heating the material in such a way that, for example irreversible, damage occurs which forms a light-scattering structure in the layer. By way of example, the technique of laser internal engraving can be used for this purpose.

In the context of laser internal engraving, in various exemplary embodiments it is possible to use a laser which generates and emits light having a wavelength at which the layer to be engraved is transparent.

1. A method for producing an optoelectronic component, wherein the method comprises:
forming an organic functional layer structure on or above a first electrode layer; and
forming a second electrode layer on or above the organic functional layer structure;
wherein a local modification structure is formed in the first electrode layer or in the second electrode layer.

2. The method as claimed in claim 1,
wherein at at least one predefined position the local modification structure is formed by means of locally heating the material of the respective layer.

3. The method as claimed in claim 2,
wherein the local heating of the material of the respective layer is effected using a laser, preferably in such a way that a laser internal engraving of the respective layer is carried out.

4. (canceled)

5. The method as claimed in claim 1, furthermore comprising:
forming a first electrode layer on or above a substrate;
and forming a cover layer on or above the second electrode layer;
wherein preferably a local modification structure is formed in the substrate and in the cover layer.

6. The method as claimed in claim 5, furthermore comprising:
forming an optically translucent intermediate layer on or above the substrate, wherein the first electrode layer is formed on or above the optically translucent intermediate layer; and forming an encapsulation layer on or above the second electrode layer;
wherein preferably a local modification structure is formed in the optically translucent intermediate layer and in the encapsulation layer.

7. The method as claimed in claim 1,
wherein that layer in which a local modification structure is formed is formed with a layer thickness of at least 1 μm.

8. The method as claimed in claim 1,
wherein the local modification structure is formed with a size in the sub-micrometer range; or
wherein the local modification structure is formed with a size of at least one micrometer.

9. An optoelectronic component, comprising:
a first electrode layer;
an organic functional layer structure on or above the first electrode layer; and
a second electrode layer on or above the organic functional layer structure;
wherein a local modification structure is formed in the first electrode layer or in the second electrode layer.

10. (canceled)

11. The optoelectronic component as claimed in claim 9,
furthermore comprising a substrate, wherein the first electrode layer is arranged on or above the substrate; and a cover layer on or above the second electrode layer;
wherein preferably a local modification structure is formed in the substrate and in the cover layer.

12. The optoelectronic component as claimed in claim 9, furthermore comprising:
an optically translucent intermediate layer on or above the substrate, wherein the first electrode layer is arranged on or above the optically translucent intermediate layer; and an encapsulation layer on or above the second electrode layer;
wherein preferably a local modification structure is formed in the optically translucent intermediate layer and in the encapsulation layer.

13. The optoelectronic component as claimed in claim 9,
wherein that layer which has a local modification structure has a layer thickness of at least 1 μm.

14. The optoelectronic component as claimed in claim 9,
wherein the local modification structure has a size in the sub-micrometer range; or
wherein the local modification structure has a size of at least one micrometer.
